(19) United States
(12) Patent Application Publication
(10) Pub. No.: US 2017/0287843 A1
(43) Pub. Date: Oct. 5, 2017

(54) SEMICONDUCTOR DEVICE HAVING CONTACT PLUGS WITH DIFFERENT INTERFACIAL LAYERS

(71) Applicant: UNITED MICROELECTRONICS CORP., Hsin-Chu City (TW)

(72) Inventors: Jia-Rong Wu, Kaohsiung City (TW); Ying-Cheng Liu, Tainan City (TW); Ching-Wen Hung, Tainan City (TW); Yi-Hui Lee, Taipei City (TW); Chih-Sen Huang, Tainan City (TW)

(21) Appl. No.: 15/091,562

(22) Filed: Apr. 5, 2016

(51) Int. Cl. H01L 23/532; H01L 23/535; H01L 27/092

(52) U.S. Cl. CPC H01L 23/53266; H01L 27/092; H01L 23/535

(57) ABSTRACT

According to a preferred embodiment of the present invention, a semiconductor device is disclosed. The semiconductor device includes: a substrate having a first region and a second region; a first contact plug on the first region, and a second contact plug on the second region. Preferably, the first contact plug includes a first interfacial layer having a first conductive type and a first work function metal layer having the first conductive type on the first interfacial layer, and the second contact plug includes a second interfacial layer having a second conductive type and a second work function metal layer having the second conductive type on the second interfacial layer.

### BACKGROUND OF THE INVENTION

### 1. Field of the Invention

The invention relates to a semiconductor device, and more particularly to a CMOS transistor having contact plugs with interfacial layer of different conductive type.

### 2. Description of the Prior Art

With the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

However, integration of metal gate and contact plugs still faces some issues in conventional FinFET fabrication. For instance, appearance of scratches has been constantly observed after formation of metal gates to affect performance of the device. Hence, how to improve the current FinFET fabrication for resolving these issues has become an important task in this field.

### SUMMARY OF THE INVENTION

According to a preferred embodiment of the present invention, a semiconductor device is disclosed. The semiconductor device includes: a substrate having a first region and a second region; a first contact plug on the first region, and a second contact plug on the second region. Preferably, the first contact plug includes a first interfacial layer having a first conductive type and a first work function metal layer having the first conductive type on the first interfacial layer, and the second contact plug includes a second interfacial layer having a second conductive type and a second work function metal layer having the second conductive type on the second interfacial layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-10 illustrate a method for fabricating semiconductor device according to a preferred embodiment of the present invention.

### DETAILED DESCRIPTION

Referring to FIGS. 1-10, FIGS. 1-10 illustrate a method for fabricating semiconductor device according to a preferred embodiment of the present invention. As shown in FIG. 1, a substrate 12, such as a silicon substrate or silicon-on-insulator (SOI) substrate is provided, and a first region and a second region, such as a NMOS region 14 and a PMOS region 16 are defined on the substrate 12. A plurality of shallow trench isolations (STI) 18 are formed in the substrate 12 to separate the NMOS region 14 and the PMOS region 16.

Next, a plurality of gate structures, such as metal gates 20, 22 are formed on the substrate 12 of the NMOS region 14 and metal gates 24, 26 are formed on the substrate 12 of the PMOS region 16. It should be noted that even though four metal gates are disclosed in this embodiment, the quantity of the metal gates disposed on each of the NMOS region and PMOS region is not limited to two, but could by any quantity depending on the demand of the product.

It should be also be noted that since the present embodiment pertains to a planar type MOS transistor, the metal gates 20, 22, 24, 26 are disposed on the surface of the substrate 12 directly. However, it would also be desirable to apply the present invention to a non-planar transistor, such as a FinFET device, and in such instance, at least a fin-shaped structure (not shown) would be formed on the substrate 12 and the metal gates 20, 22, 24, 26 would be crossing and situating directly on top of the fin-shaped structure. If a fin-shaped structure were formed on the substrate 12, the bottom of the fin-shapes structure is preferably enclosed by a STI.

According to an embodiment of the present invention, the fin-shaped structure would preferably be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structure could also be obtained by first forming a patterned mask (not shown) on the substrate, 12, and through an etching process, the pattern of the patterned mask is transferred to the substrate 12 to form the fin-shaped structure. Moreover, the formation of the fin-shaped structure could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structure. These approaches for forming fin-shaped structure are all within the scope of the present invention.

The fabrication of the metal gates 20, 22, 24, 26 could be accomplished by a gate first process, a high-k first approach from gate last process, or a high-k last approach from gate last process. Since this embodiment pertains to a high-k last approach, dummy gates (not shown) composed of polysilicon gates could be first formed on the substrate 12, and a spacer 28 is formed on the sidewall of each dummy gate. A source/drain region 30 and/or epitaxial layer 32 are then formed on the substrate 12 adjacent to two sides of the spacer 28, a contact etch stop layer (CESL) 34 is formed on the dummy gates, and an interlayer dielectric (ILD) layer 36 composed of tetraethyl orthosilicate (TEOS) is formed on the CESL 34.

Next, a replacement metal gate (RMG) process is conducted to planarize part of the ILD layer 36 and part of the CESL 32 and then transform the dummy gates into metal gates 20, 22, 24, 26. The RMG process could be accomplished by first performing a selective dry etching or wet etching process, such as using etchants including ammonium hydroxide (NH₄OH) or tetramethylammonium hydroxide (TMAH) to remove the polysilicon material from dummy gates for forming recesses (not shown) in the ILD layer 36. Next, a high-k dielectric layer 38 and a conductive layer including at least a U-shaped work function metal layer 40 and a low resistance metal layer 42 are formed in the recesses, and a planarizing process is conducted so that the surfaces of the U-shaped high-k dielectric layer 38, U-shaped work function metal layer 40, low resistance metal layer 42, and ILD layer 36 are coplanar.

In this embodiment, the high-k dielectric layer 38 is preferably selected from dielectric materials having dielectric constant (k value) larger than 4. For instance, the high-k dielectric layer 38 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 40 is formed for tuning the work function of the later formed metal gates to be appropriate in an NMOS or a PMOS. For an NMOS transistor, the work function metal layer 40 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 40 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 40 and the low resistance metal layer 42, in which the material of the barrier layer may include titanium (Ti), titanium nitride (TiN), tantalum (Ta) or tantalum nitride (TaN). Furthermore, the material of the low-resistance metal layer 42 may include copper (Cu), aluminum (Al), titanium aluminum (TiAl), cobalt tungsten phosphide (CoWP) or any combination thereof. Since the process of using RMG process to transform dummy gate into metal gate is well known to those skilled in the art, the details of which are not explained herein for the sake of brevity.

Next, part of the high-k dielectric layer 38, part of the work function metal layer 40, and part of the low resistance metal layer 42 are removed to form recesses (not shown), and a hard mask 44 is formed in each recess so that the top surfaces of the hard mask 44 and ILD layer 36 are coplanar. The hard mask 44 could be selected from the group consisting of silicon oxide, silicon nitride, silicon oxynitride, and silicon carbon nitride.

Next, a dielectric layer 46 is formed on the ILD layer and a photo-etching process is conducted to remove part of the dielectric layer 46 and part of the ILD layer 36 adjacent to the metal gates 20, 22, 24, 26 for forming contact holes 48, 50.

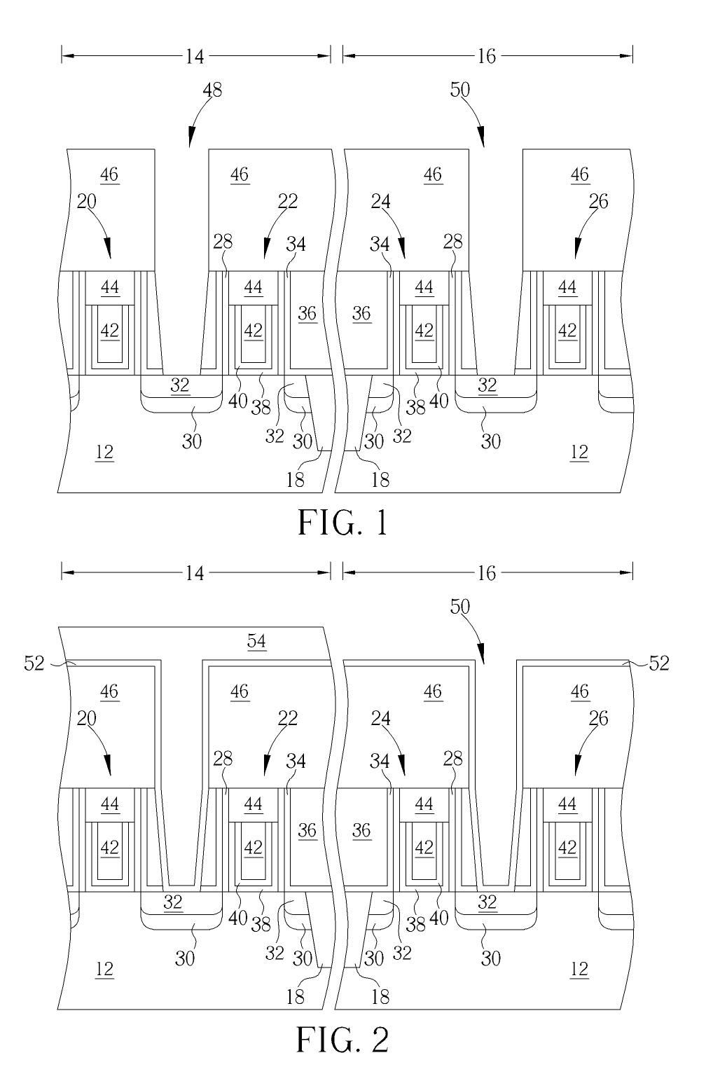

Next, as shown in FIG. 2, an interfacial layer 52 is deposited on the dielectric layer 46 and into the contact holes 48, 50. Preferably, the interfacial layer 52 is a n-type interfacial layer, which could be selected from the group consisting of TiOₓ, AlOₓ, SiN, and ZnO. Next, a patterned mask, such as a patterned resist 54 is formed on the interfacial layer 52 on the NMOS region 14.

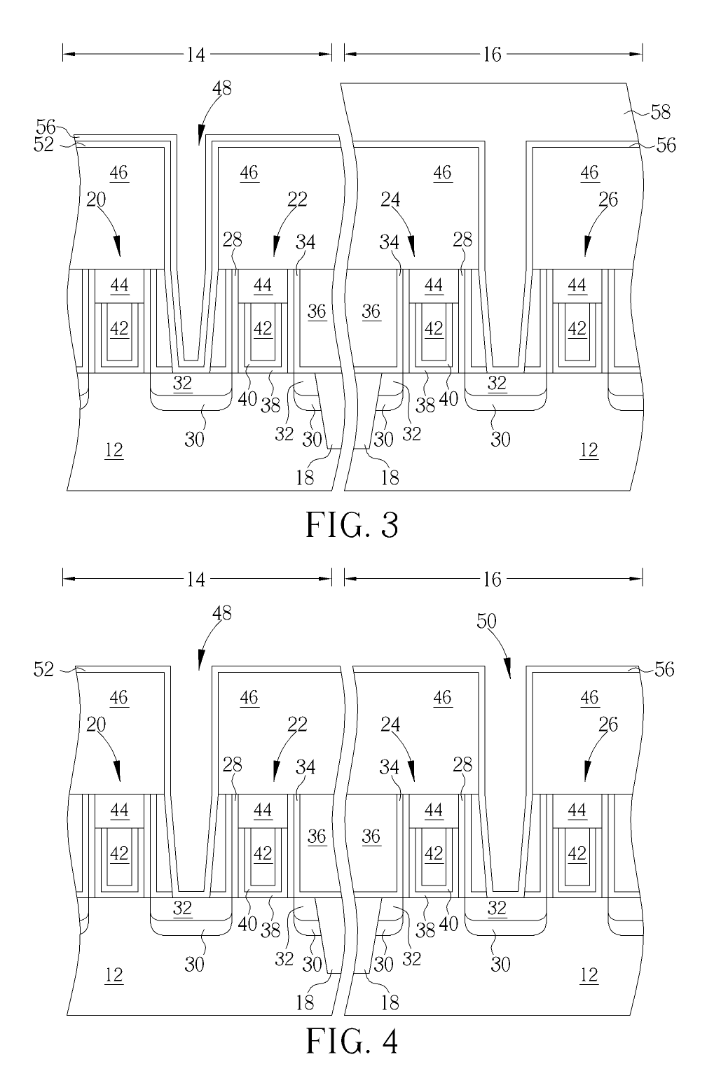

Next, as shown in FIG. 3, an etching process is conducted by using the patterned resist 54 as mask to remove part of the interfacial layer 52 on the PMOS region 16. This exposes the bottom surface and sidewalls of the contact hole 50. The patterned resist 54 is stripped thereafter.

Next, another interfacial layer 56 is deposited on the interfacial layer 52 on NMOS region 14, the dielectric layer 46 on PMOS region 16, and filled into the contact hole 50 on PMOS region 16. Preferably, the interfacial layer 56 is a p-type interfacial layer, which could be selected from the group consisting of NiO, AlOₓ, and SiN. Next, another patterned resist 58 is formed on the interfacial layer 56 to cover the PMOS region 16.

Next, as shown in FIG. 4, an etching process is conducted by using the patterned resist 58 as mask to remove part of the interfacial layer 56 on the NMOS region 14 and expose the interfacial layer 52 underneath. The patterned resist 58 is stripped thereafter.

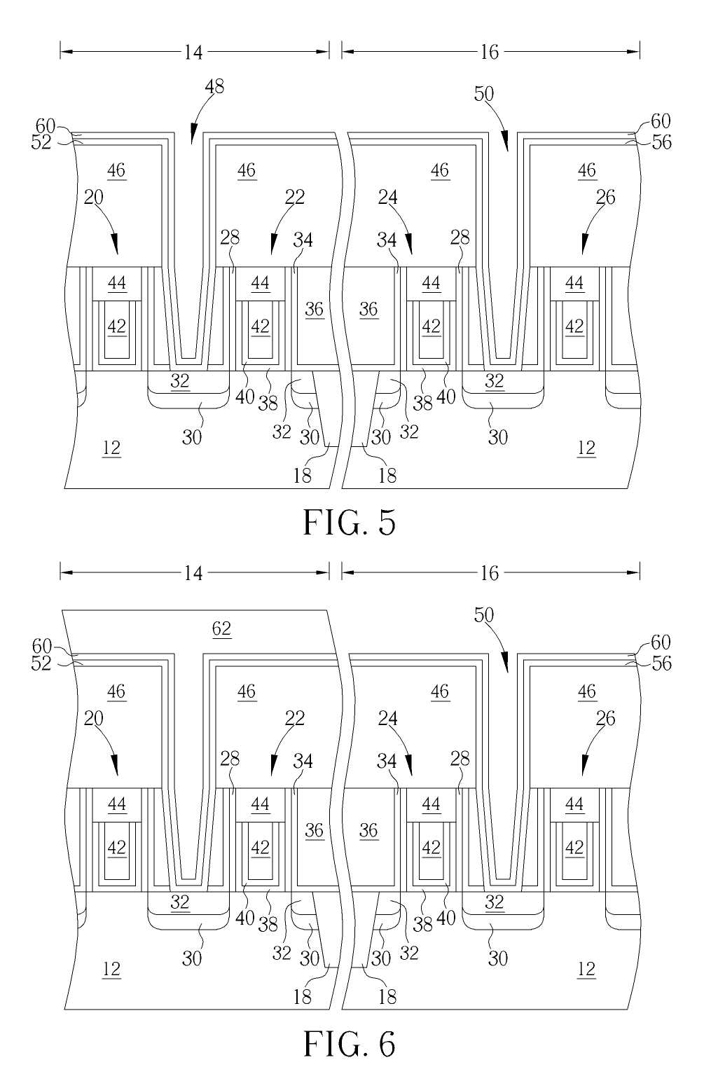

Next, as shown in FIG. 5, a work function metal layer 60 is deposited on the interfacial layer 52 on NMOS region 14 and the interfacial layer 56 on PMOS region 16. Preferably, the work function metal layer 60 is a n-type work function metal layer. Similar to the work function metal layer 40 formed in the metal gates 20, 22, 24, 26, the work function metal layer 60 adapted for NMOS transistor preferably has a work function ranging between 3.9 eV and 4.3 eV and maybe selected from the group consisting of titanium aluminide (TiAl), zirconium aluminide (ZrAl), tungsten aluminide (WAl), tantalum aluminide (TaAl), hafnium aluminide (HfAl), and titanium aluminum carbide (TiAlC), but not limited thereto.

Next, as shown in FIG. 6, a patterned resist 62 is formed on the work function metal layer 60 to cover the NMOS region 14.

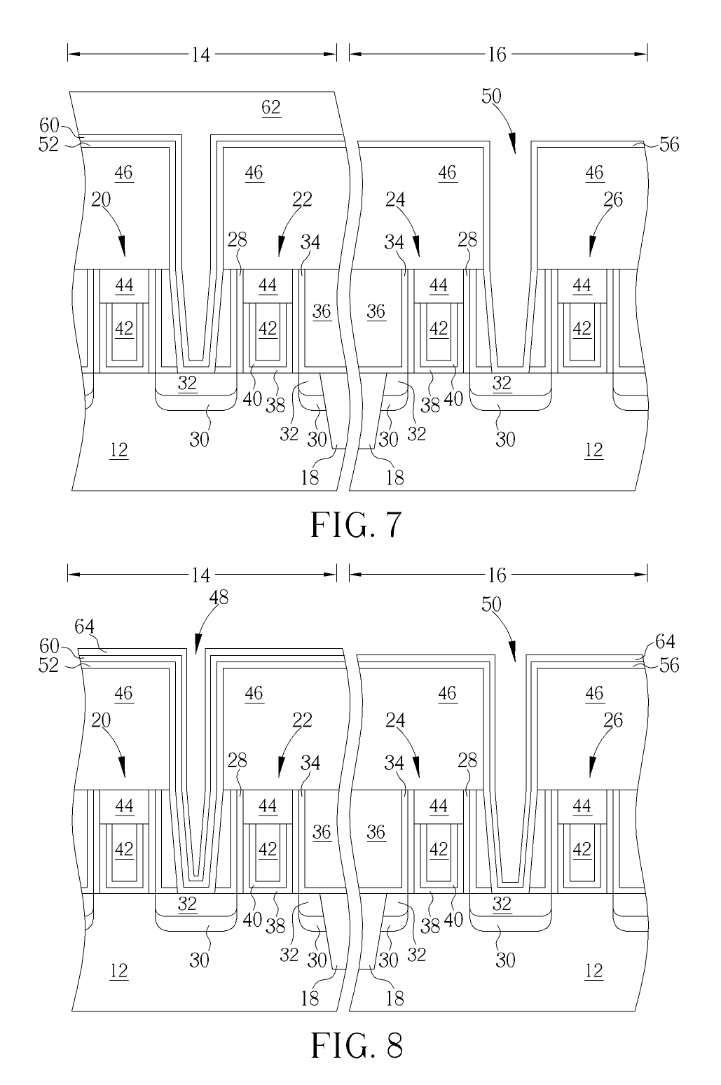

Next, as shown in FIG. 7, an etching process is conducted by using the patterned resist 62 as mask to remove the work function metal layer 60 on the PMOS region 16 and expose the interfacial layer 56 underneath. The patterned resist 62 is stripped thereafter.

Next, as shown in FIG. 8, another work function metal layer 64 is deposited on the work function metal layer 60 on NMOS region 14 and the interfacial layer 56 on PMOS region 16. Preferably, the work function metal layer 64 is a p-type work function metal layer. Similar to the work function metal layer 40 formed in the metal gates 20, 22, 24, 26, the work function metal layer 64 adapted for PMOS transistor preferably has a work function ranging between 4.8 eV and 5.2 eV and may be selected from the group consisting of titanium nitride (TiN), tantalum nitride (TaN), and tantalum carbide (TaC), but not limited thereto.

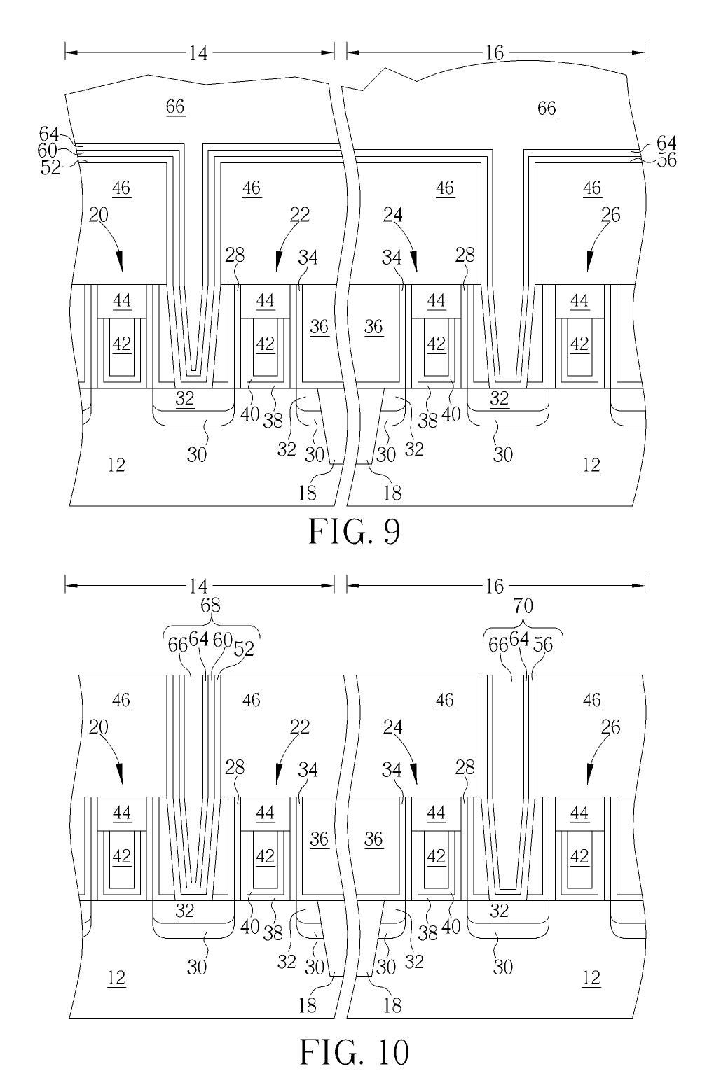

Next, as shown in FIG. 9, a low resistance metal layer 66 is formed on the work function metal layer 64 on both NMOS region 14 and PMOS region 16. According to an embodiment of the present invention, an optional barrier layer (not shown) could be formed between the work function metal layer 64 and the low resistance metal layer 66, in which the material of the barrier layer may include titanium (Ti), titanium nitride (TiN), tantalum (Ta) or tantalum nitride (TaN). Furthermore, the material of the low-resistance metal layer 66 may include copper (Cu), aluminum (Al), titanium aluminum (TiAl), cobalt tungsten phosphide (CoWP) or any combination thereof.

Next, as shown in FIG. 10, a planarizing process, such as a CMP process is conducted to remove part of the low resistance metal layer 66, part of the work function metal layer 64, part of the work function metal layer 60, part of the interfacial layer 56, and part of the interfacial layer 52. This forms a contact plug 68 on the NMOS region 14 and another contact plug 70 on the PMOS region 16.

Preferably, the contact plug 68 on the NMOS region 14 is composed of a U-shaped n-type interfacial layer 52, a U-shaped n-type work function metal layer 60, a U-shaped p-type work function metal layer 64, and a low resistance metal layer 66. The contact plug 70 on the PMOS region 16 on the other hand, is composed of a U-shaped p-type interfacial layer 56, a U-shaped p-type work function metal layer 64, and a low resistance metal layer 66.

It should be noted that even though interfacial layers of same conductive type are disposed to form contact plugs 68 and 70 on NMOS region 14 and PMOS region 16 respectively, it would also be desirable to form interfacial layers of opposite conductive type to form contact plugs on NMOS region 14 and PMOS region 16 according to an embodiment of the present invention. For instance, a contact plug (not shown) on NMOS region 14 could include a p-type interfacial layer, a n-type work function metal layer, a p-type work function metal layer, and a low resistance metal layer, while a contact plug (not shown) on PMOS region 16 could include a n-type interfacial layer, a p-type work function metal layer, and a low resistance metal layer, which is also within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

1. A semiconductor device, comprising:
a substrate having a first region and a second region;
a first contact plug on the first region, wherein the first contact plug comprises:
a first interfacial layer having a first conductive type;
a first work function metal layer having the first conductive type on the first interfacial layer; and
a third work function metal layer having a second conductive type on the first work function metal layer;
a second contact plug on the second region, wherein the second contact plug comprises:
a second interfacial layer having the second conductive type, wherein the first conductive type and the second conductive type are different conductive types; and
a second work function metal layer having the second conductive type on the second interfacial layer.

2. The semiconductor device of claim 1, further comprising a low resistance metal layer on the first work function metal layer and the second work function metal layer.

3. The semiconductor device of claim 2, wherein the low resistance metal layer comprises tungsten.

4. The semiconductor device of claim 1, wherein the first conductive type is n-type and the second conductive type is p-type.

5. The semiconductor device of claim 4, wherein the first interfacial layer is selected from the group consisting of TiOₓ, AlOₓ, SiN, and ZnO.

6. The semiconductor device of claim 4, wherein the second interfacial layer is selected from the group consisting of NiO, AlOₓ, and SiN.

7. (canceled)

8. The semiconductor device of claim 1, wherein the first conductive type is p-type and the second conductive type is n-type.

9. The semiconductor device of claim 8, wherein the first interfacial layer is selected from the group consisting of NiO, AlOₓ, and SiN.

10. The semiconductor device of claim 8, wherein the second interfacial layer is selected from the group consisting of TiOₓ, AlOₓ, SiN, and ZnO.

11. (canceled)
